(19) United States
(12) Patent Application Publication
(10) Pub. No.: US 2008/0220344 A1
(43) Pub. Date: Sep. 11, 2008

(54) Drawing Method and Apparatus

(76) Inventors: Daisuke Nakaya, Kawagawa-ken (JP); Toru Katayama, Kanagawa-ken (JP); Takashi Fukui, Kanagawa-ken (JP); Manabu Mizumoto, Kanagawa-ken (JP); Susumu Tomiyama, Kanagawa-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/989,532

(22) PCT Filed: Jul. 28, 2006
(86) PCT No.: PCT/JP2006/315023

§ 371 Date: Jan. 28, 2008

(30) Foreign Application Priority Data
Jul. 29, 2005 (JP) 2005-220604

(51) Int. Cl. G03F 9/00; G03F 7/20; G02B 7/182

(52) U.S. Cl. 430/22; 430/30; 359/855; 359/223

(57) ABSTRACT

In a drawing method for drawing an image on a substrate by relatively moving a drawing head that forms, based on input drawing-point data, drawing points on the substrate with respect to the substrate and by sequentially forming the drawing points on the substrate by the drawing head based on the movement of the drawing head, a relative positional deviation between the substrate and the drawing head during drawing of the image is obtained. Further, formation positions of the drawing points by the drawing head are corrected based on the obtained relative positional deviation.

### TECHNICAL FIELD

The present invention relates to a drawing method and apparatus for drawing an image on a substrate by relatively moving a drawing head that forms, based on input drawing-point data, drawing points on the substrate with respect to the substrate and by sequentially forming the drawing points on the substrate using the drawing head based on the movement of the drawing head.

### BACKGROUND ART

Conventionally, various kinds of exposure apparatuses utilizing photolithography techniques have been proposed as apparatuses for recording predetermined patterns on printed circuit boards and substrates of flat panel displays.

As an example of such exposure apparatuses, an exposure apparatus that forms a circuit pattern by scanning a substrate that is coated with photoresist with a light beam in a main scan direction and in a sub-scan direction while modulating the light beam based on exposure image data representing the circuit pattern has been proposed.

Further, as another example of such exposure apparatuses, an exposure apparatus that performs exposure by utilizing a spatial light modulator, such as a digital micromirror device (hereinafter, referred to as “DMD”), has been proposed. In the exposure apparatus, exposure is performed by modulating a light beam based on exposure image data using the spatial light modulator.

As the exposure apparatus using the DMD, the following exposure apparatus has been proposed, for example. In the exposure apparatus, the DMD is relatively moved with respect to an exposure surface, and a multiplicity of exposure-point data sets corresponding to a multiplicity of micromirrors of the DMD are input based on the movement of the DMD. Then, groups of exposure points corresponding to the micromirrors of the DMD are sequentially formed in time series. Accordingly, a desirable exposure image is formed on the exposure surface (please refer to Japanese Unexamined Patent Publication No. 2004-233718, for example).

Here, when a predetermined circuit pattern is formed on a substrate by exposure using the aforementioned exposure apparatus, it is necessary to perform exposure so that a desirable circuit pattern is formed at a desirable position of the substrate. Therefore, very accurate positioning is required.

However, in some cases, the relative position of the DMD with respect to the exposure surface temporarily deviates (misaligns or shifts), for example, due to influence of vibration transmitted to the exposure apparatus because of the setting condition of the apparatus or the like. Consequently, the quality of an exposure image becomes lower.

Therefore, as a method for solving this problem, the following method is known. In the method, an exposure head in which a DMD is set and a stage on which a substrate should be mounted are installed on an active-type or passive-type anti-vibration apparatus (please refer to Japanese Unexamined Patent Publication No. 11 (1999)-327657, for example).

### DISCLOSURE OF INVENTION

### Problems to be Solved by the Invention

However, there is a problem that the cost of the anti-vibration apparatus becomes extremely high if the exposure apparatus is large and heavy.

In view of the foregoing circumstances, it is an object of the present invention to provide a drawing method and apparatus, in which degrading of image quality caused by influence of vibration can be prevented without increasing cost when the drawing method and apparatus is used in an apparatus, such as the aforementioned exposure apparatus.

### Means for Solving the Problem

A drawing method according to the present invention is a drawing method for drawing an image on a substrate by relatively moving a drawing head that forms, based on input drawing-point data, drawing points on the substrate with respect to the substrate and by sequentially forming the drawing points on the substrate by the drawing head based on the movement of the drawing head, the method comprising the steps of:

obtaining a relative positional deviation between the substrate and the drawing head during drawing of the image; and

correcting, based on the obtained relative positional deviation, formation positions of the drawing points by the drawing head.

Further, in the drawing method according to the present invention, a relative positional deviation between the substrate and the drawing head with respect to the direction of the movement during drawing of the image may be obtained and a relative positional deviation between the substrate and the drawing head with respect to a direction orthogonal to the direction of the movement during drawing of the image may be obtained. Further, the position of a stage, on which the substrate is mounted, with respect to the direction of the movement and the position of the drawing head with respect to the direction of the movement during drawing of the image may be obtained, and the relative positional deviation with respect to the direction of the movement may be obtained based on the position of the stage with respect to the direction of the movement and the position of the drawing head with respect to the direction of the movement.

Further, the position of the stage, on which the substrate is mounted, with respect to the direction of the movement during drawing of the image may be used to control the position of the stage and to obtain the relative positional deviation with respect to the direction of the movement.

Further, the position of a stage, on which the substrate is mounted, with respect to the direction orthogonal to the direction of the movement during drawing of the image and the position of the drawing head with respect to the direction orthogonal to the direction of the movement during drawing of the image may be obtained. Further, the relative positional deviation with respect to the direction orthogonal to the direction of the movement may be obtained based on the position of the stage with respect to the direction orthogonal to the direction of the movement and the position of the drawing head with respect to the direction orthogonal to the direction of the movement.

Further, a result of obtainment of the position of the stage, on which the substrate is mounted, with respect to the direction orthogonal to the direction of the movement during drawing of the image may be used to control the position of the stage and to obtain the relative positional deviation with respect to the direction orthogonal to the direction of the movement.

Further, the formation positions of the drawing points may be corrected by controlling, based on the relative positional deviation with respect to the direction of the movement, timing of formation of the drawing points by the drawing head.

Further, a stage, on which the substrate is mounted, may be controlled so that a relative positional deviation with respect to the direction of the movement is suppressed.

Further, the formation positions of the drawing points may be corrected by performing, based on the relative positional deviation with respect to a direction orthogonal to the direction of the movement, shift processing on image data representing the image, the image data including the drawing-point data, with respect to a direction corresponding to the direction orthogonal to the direction of the movement.

Further, a stage, on which the substrate is mounted, may be controlled so that a relative positional deviation with respect to a direction orthogonal to the direction of the movement is suppressed.

Further, the drawing head may form the drawing points by illuminating the substrate with a light beam by outputting the light beam. Further, an optical system that can move, with respect to a direction orthogonal to the direction of the movement, an illumination position of the light beam that has been output from the drawing head may be provided. Further, the formation positions of the drawing points may be corrected by moving, based on a relative positional deviation with respect to the direction orthogonal to the direction of the movement, the illumination position of the light beam in the direction orthogonal to the direction of the movement using the optical system.

Further, a plurality of drawing heads may be provided, and a relative positional deviation for each of the drawing heads may be obtained based on a relative positional relationship between each of the drawing heads and the substrate.

A drawing apparatus according to the present invention is a drawing apparatus for drawing an image on a substrate by relatively moving a drawing head that forms, based on input drawing-point data, drawing points on the substrate with respect to the substrate and by sequentially forming the drawing points on the substrate by the drawing head based on the movement of the drawing head, the apparatus comprising:

a positional deviation obtainment means for obtaining a relative positional deviation between the substrate and the drawing head during drawing of the image; and

a correction means for correcting, based on the relative positional deviation obtained by the positional deviation obtainment means, formation positions of the drawing points by the drawing head.

Further, in the drawing apparatus according to the present invention, the positional deviation obtainment means may obtain a relative positional deviation between the substrate and the drawing head with respect to the direction of the movement during drawing of the image and a relative positional deviation between the substrate and the drawing head with respect to a direction orthogonal to the direction of the movement during drawing of the image. Further, the positional deviation obtainment means may obtain the position of a stage, on which the substrate is mounted, with respect to the direction of the movement and the position of the drawing head with respect to the direction of the movement during drawing of the image. Further, the positional deviation obtainment means may obtain the relative positional deviation with respect to the direction of the movement based on the position of the stage with respect to the direction of the movement and the position of the drawing head with respect to the direction of the movement.

Further, the position of the stage, on which the substrate is mounted, with respect to the direction of the movement during drawing of the image may be used to control the position of the stage and to obtain the relative positional deviation with respect to the direction of the movement.

Further, the positional deviation obtainment means may obtain the position of a stage, on which the substrate is mounted, with respect to the direction orthogonal to the direction of the movement during drawing of the image and the position of the drawing head with respect to the direction orthogonal to the direction of the movement during drawing of the image. Further, the positional deviation obtainment means may obtain the relative positional deviation with respect to the direction orthogonal to the direction of the movement based on the position of the stage with respect to the direction orthogonal to the direction of the movement and the position of the drawing head with respect to the direction orthogonal to the direction of the movement.

Further, a result of obtainment of the position of the stage, on which the substrate is mounted, with respect to the direction orthogonal to the direction of the movement during drawing of the image may be used to control the position of the stage and to obtain the relative positional deviation with respect to the direction orthogonal to the direction of the movement.

Further, the correction means may correct the formation positions of the drawing points by controlling, based on the relative positional deviation with respect to the direction of the movement, timing of formation of the drawing points by the drawing head. Further, the correction means may control a stage, on which the substrate is mounted, so that a relative positional deviation with respect to the direction of the movement is suppressed.

Further, the correction means may correct the formation positions of the drawing points by performing, based on the relative positional deviation with respect to a direction orthogonal to the direction of the movement, shift processing on image data representing the image, the image data including the drawing-point data, with respect to a direction corresponding to the direction orthogonal to the direction of the movement. Further, the correction means may control a stage, on which the substrate is mounted, so that a relative positional deviation with respect to a direction orthogonal to the direction of the movement is suppressed.

Further, the drawing head may form the drawing points by illuminating the substrate with a light beam by outputting the light beam. Further, an optical system that can move, with respect to a direction orthogonal to the direction of the movement, an illumination position of the light beam that has been output from the drawing head may be provided. Further, the correction means may correct the formation positions of the drawing points by moving, based on a relative positional deviation with respect to the direction orthogonal to the direction of the movement, the illumination position of the light beam in the direction orthogonal to the direction of the movement using the optical system.

Further, a plurality of drawing heads may be provided, and the positional deviation obtainment means may obtain a relative positional deviation for each of the drawing heads based on a relative positional relationship between each of the drawing heads and the substrate.

### EFFECTS OF THE INVENTION

According to the drawing method and apparatus of the present invention, a relative positional deviation between the substrate and the drawing head during drawing of an image is obtained, and formation positions of the drawing points by the drawing head are corrected based on the obtained relative positional deviation. Therefore, even if the relative position of the substrate and the drawing head deviates (shifts or misaligns) due to influence of vibration caused by the setting condition of the apparatus or the like, the formation positions of the drawing points are corrected in real time based on the positional deviation. Consequently, it is possible to draw an image at a desirable position of the substrate and to prevent the aforementioned degrading of image quality.

### BRIEF DESCRIPTION OF DRAWINGS

FIG. 1 is a schematic perspective view illustrating the structure of an exposure apparatus using first and second embodiments of a drawing method and apparatus according to the present invention;

FIG. 2 is a perspective view illustrating the structure of a scanner of an exposure apparatus;

in FIG. 3, Diagram A is a plan view illustrating exposed areas formed on an exposure surface of a substrate and Diagram B is a plan view illustrating the arrangement of exposure areas formed by respective exposure heads;

FIG. 4 is a diagram illustrating a DMD in an exposure head of an exposure apparatus;

FIG. 5 is a block diagram illustrating the electrical configuration of an exposure apparatus;

FIG. 6 is a diagram illustrating an X-direction position information measurement unit and a Y-direction position information measurement unit in an exposure apparatus;

FIG. 7 is a diagram for explaining a method for obtaining a displacement amount of a movable stage with respect to X direction;

FIG. 8 is a diagram illustrating a meander line obtained from displacement amounts of the movable stage with respect to X direction;

FIG. 9 is a diagram for explaining a method for obtaining a displacement amount of the movable stage with respect to Y direction;

FIG. 10 is a diagram illustrating displacement amounts of the movable stage with respect to Y direction;

FIG. 11 is a diagram showing pulse correction numbers at reset timing obtained based on displacement amounts of the movable stage with respect to Y direction;

FIG. 12 is a diagram illustrating divided exposure image data;

FIG. 13 is a diagram for explaining a method for performing shift processing on the divided exposure image data;

FIG. 14 is a diagram illustrating an example of an exposure image obtained by performing shift processing on divided exposure image data for each of exposure heads and by controlling reset timing of the respective exposure heads;

FIG. 15 is a diagram illustrating a part of an exposure apparatus using a second embodiment of a drawing method and apparatus of the present invention;

FIG. 16 is a diagram illustrating a part of an exposure apparatus using another embodiment of a drawing method and apparatus of the present invention; and

FIG. 17 is a diagram illustrating exposure timing of exposure heads.

### BEST MODE FOR CARRYING OUT THE INVENTION

Hereinafter, an exposure apparatus using a first embodiment of a drawing method and apparatus of the present invention will be described in detail with reference to the attached drawings.

In the exposure apparatus using the first embodiment of the present invention, a displacement amount of a movable stage that conveys a substrate is obtained in advance by measurement. Further, a displacement amount of the movable stage caused by a disturbance (external disturbance) or the like is measured in real time during exposure of the substrate to light. The exposure apparatus performs exposure so that a desirable exposure image is formed at a desirable position of the substrate by taking both the displacement amount that has been measured in advance and the displacement amount that is measured in real time into consideration.

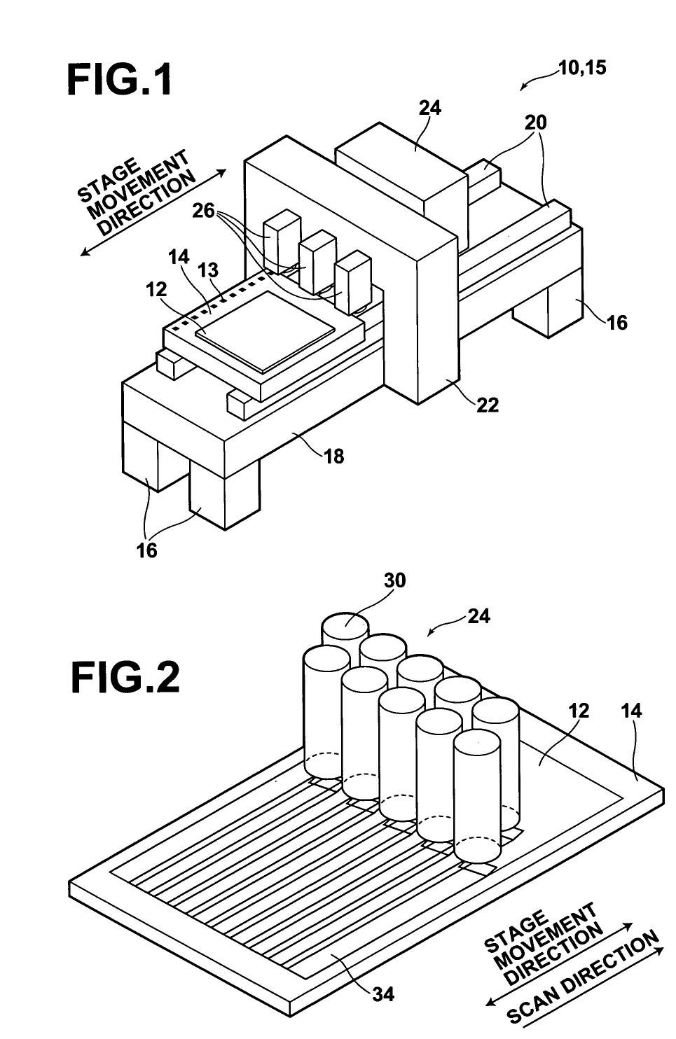

First, the schematic structure of the exposure apparatus using the first embodiment of the present invention will be described. FIG. 1 is a schematic perspective view illustrating the structure of the exposure apparatus using the first embodiment of the present invention.

As illustrated in FIG. 1, an exposure apparatus 10 includes a flat-plate-shaped movable stage (flat-plate-shaped movement stage) 14 that holds a substrate 12 on a surface thereof by suction. Further, a thick-plate-shaped base 18 for setting is supported by four legs 16, and two guides 20 extending along the movement direction of the stage are set on the upper surface of the base 18 for setting. The movable stage 14 is placed in such a manner that the longitudinal direction thereof extends in the movement direction of the stage. Further, the movable stage 14 is supported by the guides 20 in such a manner that the movable stage 14 can move back and forth. The exposure apparatus 10 further includes a movement mechanism (not illustrated) and a linear encoder (not illustrated). The movement mechanism moves the movable stage 14 in the movement direction of the stage. The linear encoder outputs pulse signals as the movable stage 14 moves. The exposure apparatus 10 can detect information about the position of the movable stage 14 and a scan speed by detecting the pulse signals output by the linear encoder.

The substrate 12 is positioned on the upper surface of the movable stage 14. Further, markings 13 are provided on the upper surface of the movable stage 14. The markings 13 are provided on one side of the substrate 12 at a predetermined interval (in the present embodiment, an interval of 50.0 mm) along Y direction.

Further, a Japanese-KO-shaped (C-shaped) gate 22 is provided at a central part of the base 18 for setting in such a manner that the gate 22 straddles the movement path of the movable stage 14. Each end of the Japanese-KO-shaped gate 22 is fixed onto either side of the base 18 for setting. Further, a scanner 24 is provided on one side of the gate 22, and a plurality of cameras 26 are provided on the other side of the gate 22. The plurality of cameras 26 photograph (image) the leading edge and the rear edge of the substrate 12 and the markings 13 provided on the movable stage 14.

Each of the scanner 24 and the cameras 26 is attached to the gate 22 and fixed at an upper position of the movement path of the movable stage 14.

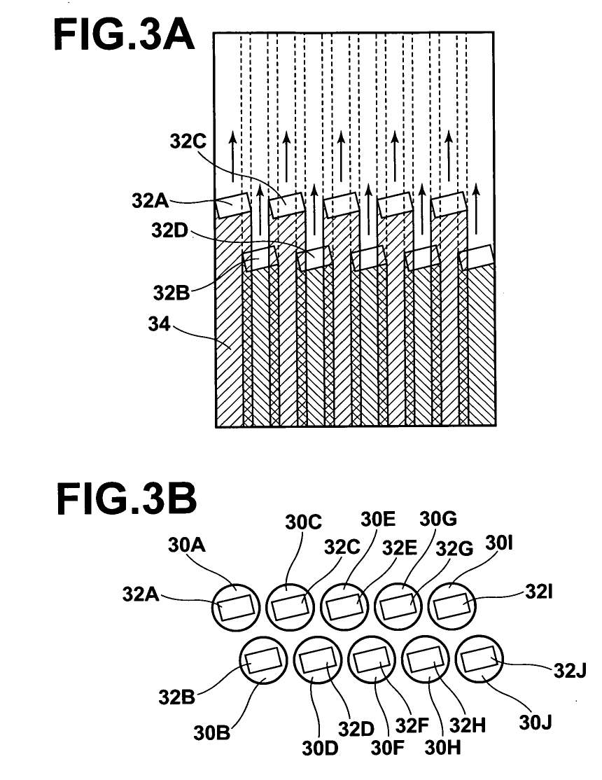

The scanner 24 includes ten exposure heads 30 (30A through 30J), as illustrated in FIGS. 2 and 3B. The ten exposure heads 30 are arranged substantially in matrix form of two rows by five columns.

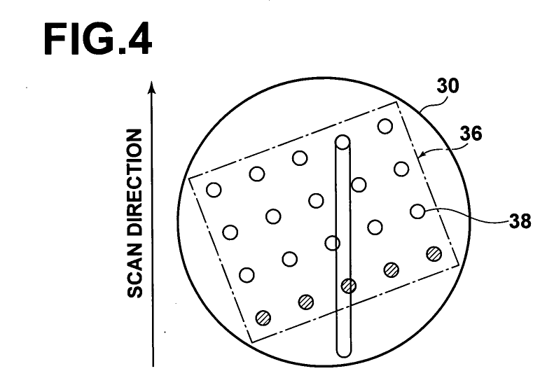

Further, a digital micromirror device (DMD) 36 is provided in each of the exposure heads 30, as illustrated in FIG. 4. The digital micromirror device 36 is a spatial light modulator (SLM)), which performs spatial light modulation on an incident light beam. In the DMD 36, a multiplicity of micromirrors 38 are two-dimensionally arranged in orthogonal directions. The DMD is attached to each of the exposure heads 30 in such a manner that the column direction of the micromirrors 38 forms a predetermined set inclination angle θ (0°<θ<90°) with respect to a scan direction. Therefore, an exposure area 32 formed by each of the exposure heads 30 is a rectangular area inclined with respect to the scan direction. While the movable stage 14 moves, each of the exposure heads 30 outputs a plurality of light beams onto the substrate 12 at predetermined timing. Accordingly, a band-shaped exposed area 34 is formed by each of the exposure heads 30, as illustrated in FIG. 3A. A light source for emitting a light beam to each of the exposure heads 30 is not illustrated. As the light source, a laser light source or the like may be used.

In the DMD 36, which is provided in each of the exposure heads 30, ON/OFF of the micromirrors 38 is controlled micromirror by micromirror. Accordingly, a dot pattern (black/white) corresponding to each of the micromirrors 38 of the DMD 36 is formed on the substrate 36 by exposure. The aforementioned band-shaped exposed area 34 is formed by two-dimensionally-arranged dots corresponding to the micromirrors 38 illustrated in FIG. 4. Further, since the DMD 36 is inclined with respect to the scan direction, as described above, it is possible to further narrow a distance between exposure points arranged in a direction orthogonal to the scan direction. Hence, it is possible to increase the resolution of an image obtained by exposure. There are cases in which some dots are not utilized because of variation in adjustment of the inclination angle. For example, in FIG. 4, shaded dots are not utilized. Therefore, micromirrors 38 of the DMD 36 corresponding to these dots are always in an OFF state.

Further, as illustrated in FIGS. 3A and B, the exposure heads 30 in each row, which are arranged in linear form, are shifted in the arrangement direction thereof by a predetermined distance so that each of the band-shaped exposed areas 34 partially overlaps with an adjacent exposed area or areas 34. Therefore, for example, an unexposed area between a leftmost exposure area 32A in the first row and an exposure area 32C on the immediate right side of the exposure area 32A is exposed by a leftmost exposure area 32B in the second row. Similarly, an unexposed area between the exposure area 32B and an exposure area 32D on the immediate right side of the exposure area 32B is exposed by the exposure area 32C.

Next, the electrical configuration of the exposure apparatus 10 will be described.

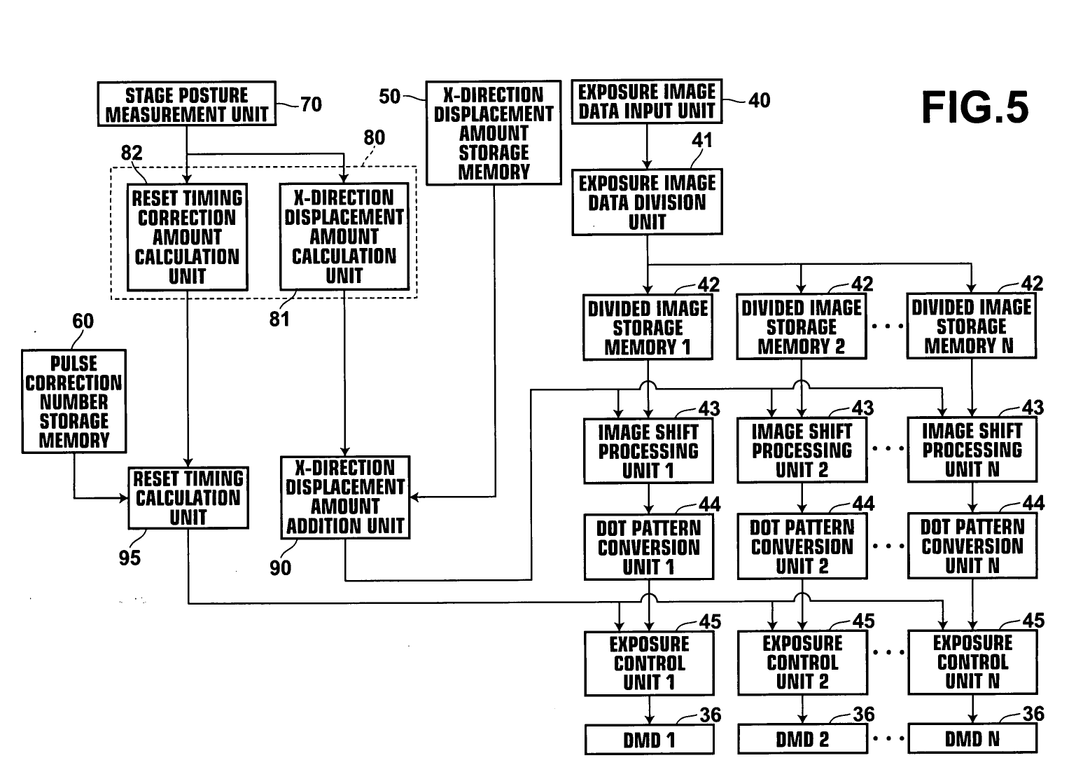

As illustrated in FIG. 5, the exposure apparatus 10 includes an exposure image data input unit 40, an exposure image data division unit 41, divided image storage memories 42, image shift processing units 43, dot pattern conversion units 44 and exposure head control units 45. The exposure image data input unit 40 receives exposure image data representing an exposure image to be formed by exposure. The exposure image data division unit 41 divides the exposure image data that has been input to the exposure image data input unit 40 into divided exposure image data for each of the exposure heads 30. The divided image storage memories 42 store the divided exposure image data for the respective exposure heads 30. The divided exposure image data is data, into which the exposure image data has been divided by the exposure image data division unit 41. The image shift processing units 43 perform shift processing on the divided exposure image data stored in the respective divided image storage memories 42. The dot pattern conversion units 44 convert the divided exposure image data, on which shift processing has been performed by the respective image shift processing units 43, into frame data. The frame data includes a dot pattern corresponding to the beam position of each of the micromirrors 38 of the DMD 36. The exposure head control units 45 output control signals to the DMD's 36 in the respective exposure heads 30. The exposure head control units 45 output the control signals based on frame data for the respective exposure heads 30, which has been obtained by conversion by the dot pattern conversion units 44, and reset timing calculated by reset timing calculation units 95, which will be described later. The reset timing is timing of outputting a control signal from the exposure control unit 45 to the DMD 36 in the exposure head 30. Data in the DMD 36 is updated (changed or rewritten) at the reset timing, and the state of the micromirrors 38 of the DMD 36 is switched.

Further, the exposure apparatus 10 includes an X-direction displacement amount storage memory 50, a pulse correction number memory 60, a real-time displacement amount calculation unit 80, an X-direction displacement amount addition unit 90 and a reset timing calculation unit 95. The X-direction displacement amount storage memory 50 stores a displacement amount of the movable stage 14 with respect to X direction, the displacement amount having been measured in advance. The pulse correction number memory 60 stores a pulse correction number that will be described later. The pulse correction number is obtained based on a displacement amount of the movable stage 14 with respect to Y direction, the displacement amount having been measured in advance. The real-time displacement amount calculation unit 80 calculates a real-time displacement amount of the movable stage 14 during exposure of the substrate 12. The real-time displacement amount calculation unit 80 calculates the real-time displacement amount based on measurement information obtained by measurement by a stage posture measurement unit 70, which will be described later. The X-direction displacement amount addition unit 90 calculates an actual displacement amount of the movable stage 14 with respect to X direction based on the real-time displacement amount of the movable stage 14 with respect to X direction and the displacement amount stored in advance in the X-direction displacement amount memory 50. The real-time displacement amount of the movable stage 14 with respect to X direction is the displacement amount that has been calculated by the real-time displacement amount calculation unit 80. The reset timing calculation unit 95 calculates reset timing of each of the exposure heads 30 based on a pulse correction number corresponding to the real-time displacement amount of the movable stage 14 with respect to Y direction and the pulse correction number stored in advance in the pulse correction number storage memory 60. The real-time displacement amount of the movable stage 14 with respect to Y direction is the displacement amount that has been calculated by the real-time displacement amount calculation unit 80.

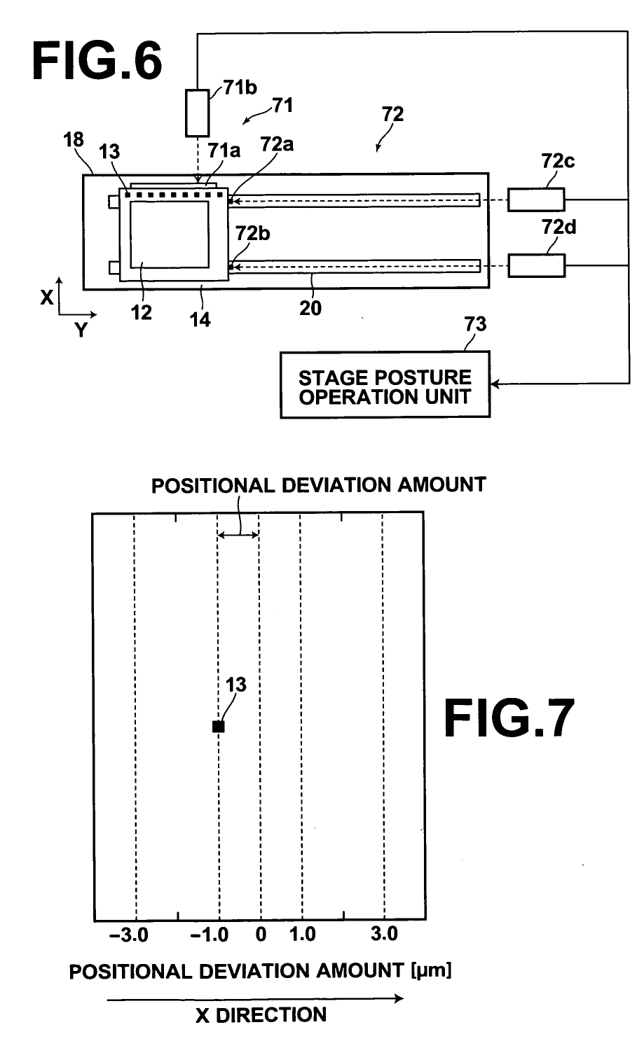

Further, as illustrated in FIG. 6, the stage posture measurement unit 70 includes an X-direction position information measurement unit 71, a Y-direction position information measurement unit 72 and a stage posture operation unit 73. The X-direction position information measurement unit 71 obtains position information about the movable stage 14 with respect to X direction by measurement. The Y-direction position information measurement unit 72 obtains position information about the movable stage 14 with respect to Y direction by measurement. The stage posture operation unit 73 obtains a real-time displacement amount of the movable stage 14 with respect to X direction, a real-time displacement amount of the movable stage 14 with respect to Y direction and a rotation amount of the movable stage 14 based on the position information measured by the X-direction position information measurement unit 71 and the position information measured by the Y-direction position information measurement unit 72.

Further, the real-time displacement amount calculation unit 80 includes an X-direction displacement amount calculation unit 81 and a reset timing correction amount calculation unit 82. The X-direction displacement amount calculation unit 81 calculates a real-time displacement amount of the movable stage 14 with respect to X direction for each of the exposure heads 30. The X-direction displacement amount calculation unit 81 calculates the real-time displacement amount based on the real-time displacement amount with respect to X direction and the rotation amount, which have been obtained by the stage posture measurement unit 70. The reset timing correction amount calculation unit 82 calculates a real-time displacement amount of the movable stage 14 with respect to Y direction for each of the exposure heads 30 based on the real-time displacement amount with respect to Y direction and the rotation amount, which have been obtained by the stage posture measurement unit 70. Further, the reset timing correction amount calculation unit 82 calculates a pulse correction number at reset timing for each of the exposure heads 30 based on the calculated real-time displacement amount. In the present embodiment, the stage posture measurement unit 70 and the real-time displacement amount calculation unit 80 form the positional deviation obtainment means recited in the claims of the present application. Further, in the present embodiment, the exposure heads 30 and the stage posture measurement unit 70 are fixed to the same case. Further, in the present embodiment, the positional deviation recited in the claims of the present application is obtained as the aforementioned real-time displacement amount.

Further, the X-direction position information measurement unit 71, illustrated in FIG. 6, includes a side mirror 71a and an X-direction laser length-measurement unit 71b. The side mirror 71a is set on one side of the movable stage 14, the side extending along the movement direction of the movable stage 14. The X-direction laser length-measurement unit 71b outputs laser light to the side mirror 71a and measures a distance (length) to the side mirror 71a by detecting light reflected from the side mirror 71a. Further, the Y-direction position information measurement unit 72 includes cube mirrors 72a and 72b, a first Y-direction laser length-measurement unit 72c and a second Y-direction laser length-measurement unit 72d. The cube mirrors 72a and 72b are set on one side of the movable stage 14, the side extending in a direction orthogonal to the movement direction of the movable stage 14. The first Y-direction laser length-measurement unit 72c outputs laser light to the cube mirror 72a and measures a distance (length) to the cube mirror 72a by detecting light reflected from the cube mirror 72a. The second Y-direction laser length-measurement unit 72d outputs laser light to the cube mirror 72b and measures a distance (length) to the cube mirror 72b by detecting light reflected from the cube mirror 72b. In FIG. 6, only one X-direction laser length-measurement unit 71b is provided. However, in actual cases, a sufficient number of X-direction laser length-measurement units 71b are provided to obtain real-time displacement amounts of the movable stage 14 with respect to X direction during exposure. Alternatively, only one X-direction laser length-measurement unit 71b may be provided and a mirror that has a sufficient length for obtaining the real-time displacement amounts may be used as the side mirror 71a.

Further, the exposure apparatus 10 includes a controller (not illustrated) for controlling the whole exposure apparatus.

The action of each of the aforementioned elements will be described later.

Next, the action of the exposure apparatus 10 will be described with reference to the drawings.

As described above, the exposure apparatus 10 measures, in advance, a displacement amount of the movable stage 14 for conveying the substrate and sets the amount obtained by measurement. Further, a displacement amount of the movable stage 14 caused by a disturbance or the like is measured in real time during exposure of the substrate 12 to light. The exposure apparatus 10 performs exposure so that a desirable exposure image is formed at a desirable position of the substrate 12 by taking both of the displacement amount measured in advance and the displacement amount measured in real time into consideration.

First, a method for setting a displacement amount of the movable stage 14 by measuring the displacement amount in advance will be described.

First, the movable stage 14 is moved by a movement mechanism from a position illustrated in FIG. 1 toward the upstream side. The upstream side is the right side of FIG. 1. In other words, the upstream side is the scanner 24 side of the gate 22. A downstream side is the left side of FIG. 1. In other words, the downstream side is the cameras 26 side of the gate 22.

After the movable stage 14 moves to the upstream-side end of its movement path, the movable stage 14 moves toward the downstream side at a desirable constant speed. As the movable stage 14 moves, pulse signals are output from the linear encoder and input to the controller.

Then, the controller counts the pulse signals output from the linear encoder. The controller outputs a control signal to the camera 26 every 1000000 pulse counts. Then, the camera 26 photographs the markings 13 provided on the movable stage 14. In the present embodiment, the linear encoder outputs a pulse signal every time when the movable stage 14 moves 0.1 μm. For the purpose of increasing adjustment resolution, the pulses at the pitch of 0.1 μm are multiplied by two (the number of the pulses is multiplied by two), and pulse signals at a pitch of 0.05 μm are output. Therefore, if the markings 13 are photographed by the camera 26 every 1000000 pulse counts as described above, it is possible to photograph in a manner that is appropriate for the interval of the markings 13 (0.05 μm/1 pulse×1000000 pulses=50 mm).

Then, photography image data obtained by photographing the markings 13 using the camera 26, as described above, is output to the controller. The controller obtains a displacement amount of the movable stage 14 with respect to X direction based on the photography image data that has been input to the controller.

Specifically, an X-direction standard line (the line of “X=0”) is set in the controller, as illustrated in FIG. 7. The positions of the images of the markings (marking images) in photography images obtained by photography by the camera 26 with respect to X direction can be judged (classified or distinguished) based on the X-direction standard line. Further, a displacement amount of the marking 13 with respect to X direction can be obtained by obtaining a positional deviation amount of the image of the marking from the X-direction standard line. The positional deviation amount of the marking image can be obtained, for example, by obtaining a deviation of the centroid (barycenter or the center of gravity) of the marking image from the X-direction standard line.

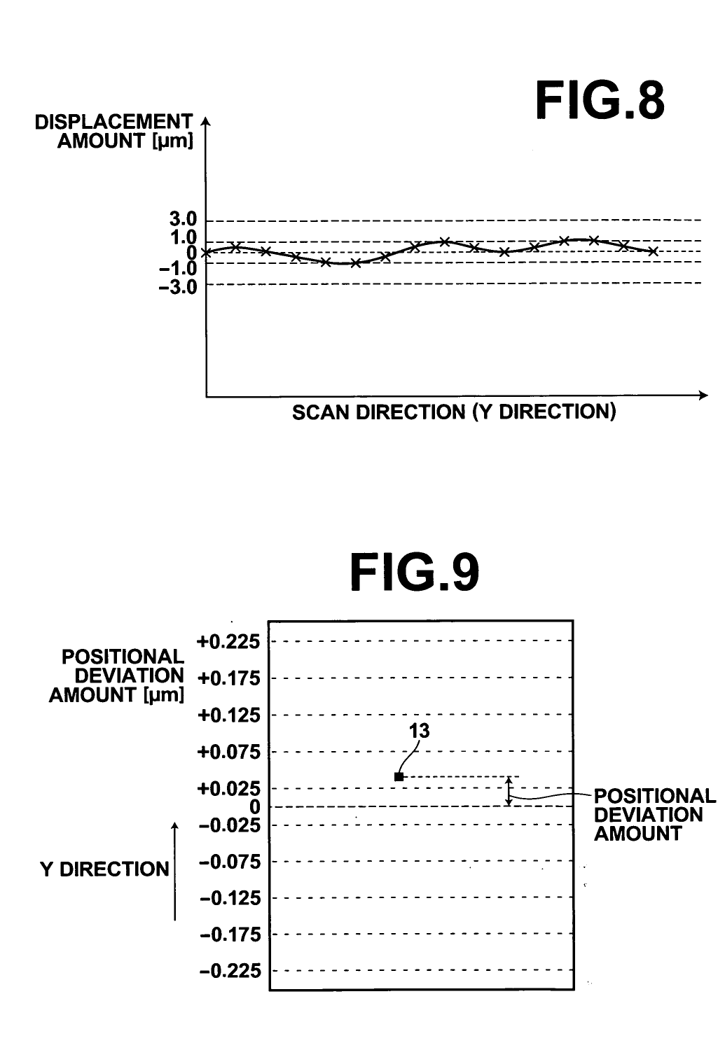

The displacement amount of each of the markings 13 is sequentially obtained based on photography image data of each of the markings 13 photographed by the camera 26. Further, the displacement amount of each of the markings 13 is plotted, as illustrated in FIG. 8. Further, a meander line, as illustrated in FIG. 8, is obtained by interpolating values between the plotted displacement amounts (indicated with x). Then, the obtained meander line is stored in the X-direction displacement amount storage memory 50.

In addition to obtaining the displacement amount of the movable stage 14 with respect to X direction based on the photography image data of the markings 13, as described above, the controller obtains a displacement amount of the movable stage 14 with respect to Y direction.

Specifically, a Y-direction standard line (the line of “Y=0”) is set in the controller, as illustrated in FIG. 9. The positions of the marking images with respect to Y direction in photography images obtained by photography by the camera 26 can be judged (classified or distinguished) based on the Y-direction standard line. A positional deviation amount of the marking image from the Y-direction standard line is obtained. The positional deviation amount of the marking image may be obtained, for example, by obtaining a deviation of the centroid of the marking image from the Y-direction standard line.

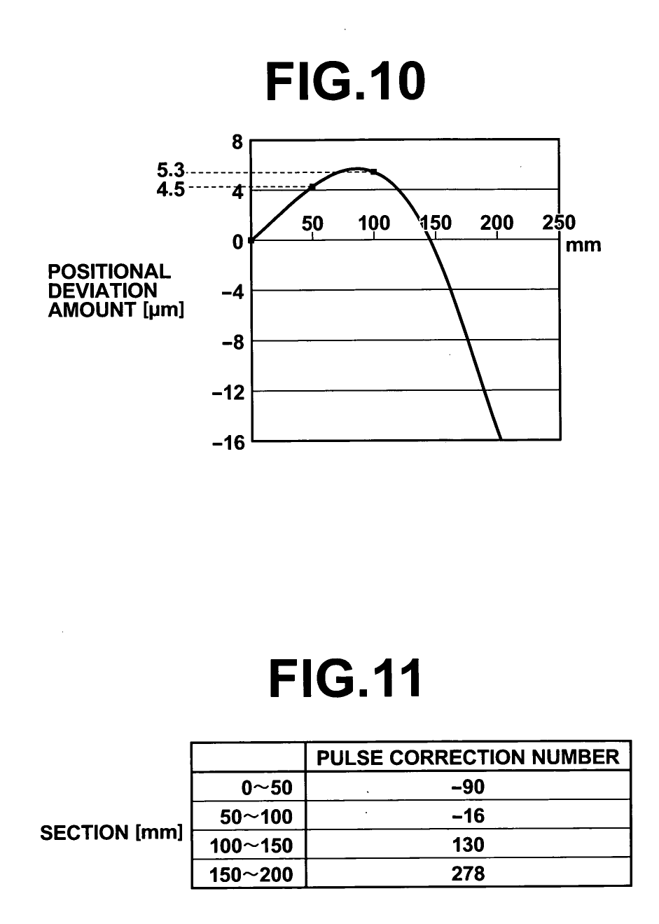

The positional deviation amount of each of the marking images is obtained, as described above. Further, an increase or decrease in the positional deviation amount from the previous positional deviation amount (the positional deviation amount of the image of the marking that was photographed immediately before) is obtained. Then, the number of pulses (pulses multiplied by two) to be output from the linear encoder to correct the increased or decreased positional deviation amount is calculated. Specifically, for example, as illustrated in FIG. 10, if when a marking 13 at the position of 50 mm is photographed, a positional deviation amount of +4.5 μm is obtained by calculation, and when a marking 13 at the position of 100 mm is photographed, a positional deviation amount of +5.3 μm is obtained by calculation, the positional deviation amount has increased by 0.8 μm (5.5 μm-4.5 μm) in the section (distance) between 50 mm and 100 mm. In other words, the positional deviation amount of the movable stage 14 in the section between 50 mm and 100 mm is 0.8 μm. In the linear encoder of the present embodiment, pulses that are multiplied by two are detected for every movement of 0.05 μm. Therefore, if correction processing for reducing the positional deviation amount by an amount corresponding to 16 pulses (0.8 μm/0.05 μm=16) is performed, it is possible to correct the displacement amount with respect to Y direction that has been generated in the section between 50 mm and 100 mm.

As described above, a pulse correction number corresponding to the displacement amount of the movable stage 14 for each section between the markings 13 is obtained based on the positional deviation amount of each of the marking images with respect to Y direction. Further, a table showing the pulse correction numbers is prepared, as illustrated in FIG. 11. The table is stored in the pulse correction number storage memory 60. The table showing the pulse correction numbers is corrected based on position information, with respect to X direction, about the camera 26 that has photographed the markings 13 and position information about each of the exposure heads 30. The table is corrected so that the pulse correction numbers correspond to the relative positional relationship between the camera 26 and each of the exposure heads 30. Accordingly, a table showing pulse correction numbers for each of the exposure heads 30 is obtained. Further, the obtained table is stored in the pulse correction number storage memory 60.

As described above, the displacement amount of the movable stage 14 with respect to X direction is obtained in advance. Further, a pulse correction number is obtained based on a displacement amount of the movable stage 14 with respect to Y direction. After the pulse correction number is obtained, the movable stage 14 is moved from the position illustrated in FIG. 1 toward the upstream side again. After the movable stage 14 is moved to the upstream end, the movable stage 14 moves toward the downstream side at a desirable constant speed.

Then, when the movable stage 14 moves toward the downstream side, each of the exposure heads 30 starts exposure of the substrate 12. Further, a real-time displacement amount of the movable stage 14 during exposure is measured. First, the method for measuring the real-time displacement amount will be described.

As described above, as the movable stage 14 moves toward the downstream side, the first Y-direction laser length-measurement unit 72c and the second Y-direction laser length-measurement unit 72d output laser light to the cube mirror 72a and the cube mirror 72b, respectively. Further, the X-direction laser length-measurement unit 71b outputs laser light to the side mirror 71a, as illustrated in FIG. 6.

Then, the laser light that has been output from the first and second Y-direction laser length-measurement units 72c and 72d is reflected by the cube mirrors 72a and 72b, respectively. Further, the reflected light is detected by the first and second Y-direction laser length-measurement units 72c and 72d. Accordingly, a distance to each of the cube mirrors 72a and 72b is measured. Further, the laser light that has been output from the X-direction laser length-measurement unit 71b is reflected by the side mirror 71a. Then, the reflected light is detected by the X-direction laser length-measurement unit 71b. Accordingly, a distance to the side mirror 71a is measured.

Then, the measurement results are output to the stage posture operation unit 73. The stage posture operation unit 73 measures position information X1 of the movable stage 14 with respect to X direction based on the measurement result by the X-direction laser length-measurement unit 71b. Further, the stage posture operation unit 73 measures position information Y1 of the movable stage 14 with respect to Y direction and position information Y2 of the movable stage 14 with respect to Y direction based on the measurement results obtained by the Y-direction laser length-measurement units 72c and 72d, respectively.

In the stage posture operation unit 73, standard position information, which is a standard when the movable stage 14 moves ideally, is set in advance. The stage posture operation unit 73 obtains a real-time displacement amount X of the movable stage 14 with respect to X direction, a real-time displacement amount Y of the movable stage 14 with respect to Y direction and a rotation amount θ of the movable stage 14 based on the standard position information and the position information X, Y1 and Y2, which have been obtained as described above.

The real-time displacement amount X with respect to X direction, the real-time displacement amount Y with respect to Y direction and the rotation amount θ should be obtained, for example, every time when reset timing is output from the exposure controller 45 to the exposure head 30. The reset timing is output every a certain number of pulse counts that have been set in advance (40 pulses in the present embodiment).

As the movable stage 14 moves, the real-time displacement amount X, the real-time displacement amount Y and the rotation amount θ are sequentially obtained, as described above. Further, the real-time displacement amount Y with respect to Y direction and the rotation amount θ are output to the reset timing correction amount calculation unit 82. The real-time displacement amount X with respect to X direction and the rotation amount θ are output to the X-direction displacement amount calculation unit 81.

Then, the reset timing correction amount calculation unit 82 sequentially obtains, based on real-time displacement amounts Y with respect to Y direction and rotation amounts θ, which are sequentially input, real-time displacement amounts Y1 through YN of the movable stage 14 for each of the exposure heads 30. The real-time displacement amounts Y1 through YN are obtained based on position information about each of the exposure heads 30 with respect to the movable stage 14 and the real-time displacement amounts Y and the rotation amounts θ of the movable stage 14.

Then, a pulse correction number for each of the exposure heads 30 is sequentially calculated in a manner similar to the aforementioned method. The pulse correction numbers are calculated based on real-time displacement amounts Y1 through YN for the respective exposure heads 30. Then, the pulse correction number for each of the exposure heads 30 is sequentially output to the reset timing calculation unit 95.

Meanwhile, the X-direction displacement amount calculation unit 81 sequentially obtains, based on real-time displacement amounts X with respect to X direction and rotation amounts θ, which are sequentially input, real-time displacement amounts X1 through XN of the movable stage 14 with respect to each of the exposure heads 30. The real-time displacement amounts X1 through XN are obtained based on position information about each of the exposure heads 30 with respect to the movable stage 14, the real-time displacement amounts X of the movable stage 14 and the rotation amounts θ of the movable stage 14.

Then, the real-time displacement amounts X1 through XN for the respective exposure heads 30, which have been obtained sequentially as described above, are sequentially output to the X-direction displacement amount addition unit 90.

Next, the exposure position of each of the exposure heads 30 with respect to X direction is corrected based on the real-time displacement amounts X1 through XN of the movable stage 14 for the respective exposure heads 30, which have been calculated by the X-direction displacement amount calculation unit 81 as described above, and the meander line stored in the X-direction displacement amount storage memory 50. Further, the reset timing of each of the exposure heads 30 is controlled based on the pulse correction number that has been calculated by the reset timing correction amount calculation unit 82, as described above, and the pulse correction number stored in the pulse correction number storage memory 60. Accordingly, an exposure image is formed at a desirable position of the substrate 12. This exposure method will be described.

First, exposure image data representing an exposure image to be formed on the substrate 12 by exposure is input to the exposure image data input unit 40. Then, the exposure image data is output from the exposure image data input unit 40 to the exposure image data division unit 41.

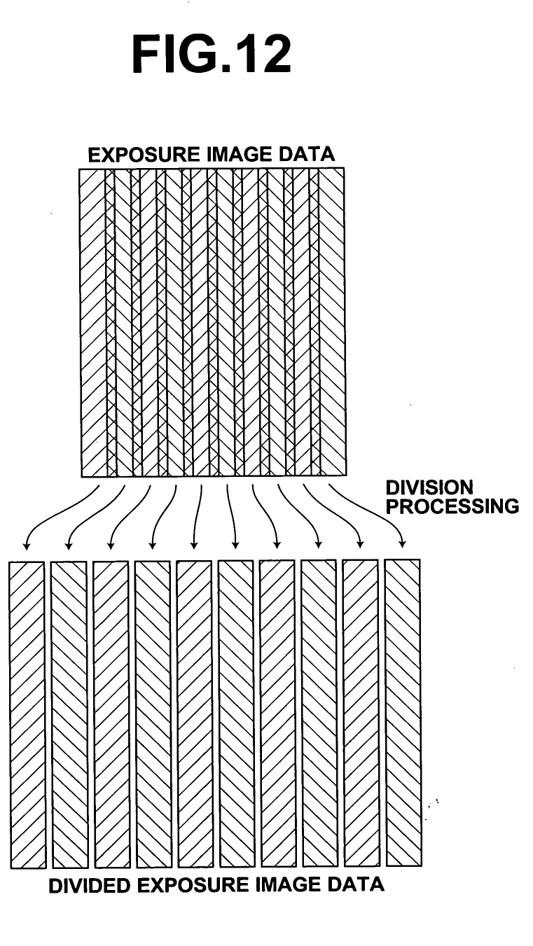

Then, the exposure image data division unit 41 divides the input exposure image data into sets of divided exposure image data for the respective exposure heads 30, as illustrated in FIG. 12. Then, the exposure image data division unit 41 stores the sets of divided exposure image data for the respective exposure heads 30 in divided image storage memories 42, respectively.

The sets of divided exposure image data for the respective exposure heads 30 are stored in the respective divided image storage memories 42, as described above. Further, the movable stage 14, on which the substrate 12 is set, moves at a desirable constant speed from the upstream side toward the downstream side.

Then, if the leading edge of the substrate 12 is detected by the camera 26, each of the exposure heads 30 starts exposure for exposing the substrate 12 to light at predetermined reset timing. At this time, the following processing is performed.

When the leading edge of the substrate 12 is detected, the image shift processing units 43 read out divided exposure image data corresponding to the positions of the respective exposure heads 30 with respect to the movable stage 14 from the respective divided image storage memories 42. Then, shift processing is performed on each of the sets of divided exposure image data for the respective exposure heads 30, which have been read out as described above.

Specifically, the X-direction displacement amount addition unit 90 obtains a displacement amount of the movable stage 14 with respect to X direction for each position (in the present embodiment, 40 pulse×0.05 μm=0.2 μm) of the movable stage 14. The displacement amount is obtained based on the meander line stored in the X-direction displacement amount storage memory 81. Then, the obtained displacement amount is added to the real-time displacement amounts X1 through XN for the respective exposure heads 30 and addition displacement amounts are obtained. The real-time displacement amounts X1 through XN are amounts that have been calculated by the X-direction displacement amount calculation unit 81. Then, the addition displacement amounts are output to the image shift processing units 43, respectively.

Then, the image shift processing units 43 perform shift processing, based on the addition displacement amounts for the respective exposure heads 30, on the input sets of divided exposure image data for the respective exposure heads 30.

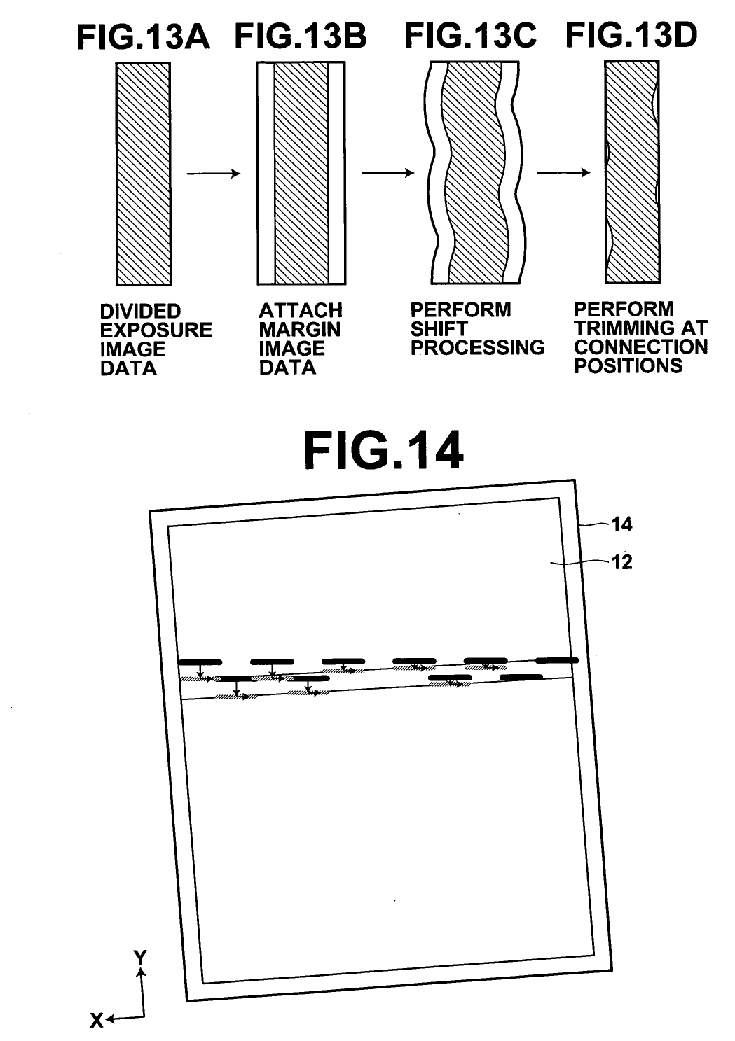

More specifically, the image shift processing units 43 attach (add) margin image data corresponding to the width of the addition displacement amount to the divided exposure image data that has been input, as illustrated in FIG. 13B. The input divided exposure image data is illustrated in FIG. 13A. Further, the image shift processing units 43 perform, based on the addition displacement amount, shift processing on the divided image data to which the margin image data has been attached, as illustrated in FIG. 13C. Further, the image shift processing units 43 perform trimming processing on the divided exposure image data on which the shift processing has been performed. The trimming processing is performed on the divided exposure image data at connection positions. Then, the image shift processing units 43 output the divided exposure image data on which trimming processing has been performed to the dot pattern conversion units 44.

Then, the dot pattern conversion units 44 extract (obtain) exposure-point data corresponding to the beam positions of the micromirrors 38 of the DMD 36 in each of the exposure heads 30 from the divided exposure image data for the respective exposure heads 30 on which shift processing has been performed as described above. Accordingly, the dot pattern conversion units 44 generate frame data including the exposure-point data.

Then, the exposure control units 45 output control signals based on the frame data that has been generated by the dot pattern conversion units 44, as described above, to the DMD's 36 in the respective exposure heads 30. The exposure control units 45 output the control signals at reset timing that is obtained by the reset timing calculation unit 95 in the following manner.

The reset timing calculation unit 95 is set in advance so that reset timing is output to each of the exposure heads 30 every 40 pulse counts of pulse signals that are output from the linear encoder. Specifically, the reset timing calculation unit 95 is set in advance so that reset timing is output once every time when the movable stage 14 moves 2.0 μm.

Then, the reset timing is controlled for each of the exposure heads 30 by increasing or decreasing the number of the pulse count that has been set in advance, which is 40 pulse count. The pulse count is increased or decreased from 40 pulse count based on the pulse correction number that is stored in the pulse correction number storage memory and the pulse correction number obtained by the reset timing correction amount calculation unit 82. The reset timing is controlled so that a desirable exposure image is formed at a desirable position of the substrate 12 with respect to Y direction.

Specifically, for example, when reset timing in the section between 50 mm and 100 mm, illustrated in FIG. 10, is calculated, a pulse correction number for the section between 50 mm and 100 mm is read out for each of the exposure heads 30. The pulse correction number is read out based on the table stored in the pulse correction number storage memory 60. For example, if the pulse correction number for the section between 50 mm and 100 mm is −16, since the reset timing in the section between 50 mm and 100 mm is 1000000 pulse/40 pulse=25000 times. Therefore, the number of pulses is corrected from 40 pulse to 39 pulse for 16 of 25000 times of reset timing. The 16 times of reset timing are predetermined reset timing. Further, the pulse number at which the reset timing is output is corrected based on the pulse correction number calculated by the reset timing correction amount calculation unit 82. Specifically, the reset timing correction amount calculation unit 82 outputs a pulse correction number for each of the exposure heads 30 to the reset timing calculation unit 95. The pulse correction number is a number obtained for every 40 pulses. Then, the pulse number that has been corrected as described above is further increased or decreased by the pulse correction number calculated by the reset correction amount calculation unit 82. Then, the reset timing is output to each of the exposure control units 45 at timing corresponding to the pulse number that has been increased or decreased.

Then, as the movable stage 14 moves, the reset timing calculation unit 95 outputs reset timing to each of the exposure control units 45 at intervals of pulses for the respective exposure control units 45. The number of the intervals of pulses for each of the exposure control units 45 is the number that has been corrected as described above. Then, each of the exposure control units 45 outputs a control signal to the respective exposure heads 30 based on the reset timing.

Then, each of the exposure heads 30 controls ON/OFF of each of the micromirrors based on the control signal output from the respective exposure control units 45 and an exposure image is formed on the substrate 12.

FIG. 14 illustrates an example of an exposure image when shift processing has been performed on the divided exposure image data for each of the exposure heads 30 as described above and reset timing has been controlled. In FIG. 14, a dark (black) area indicates the position of an exposure image when neither shift processing nor control of reset timing has been performed. In FIG. 14, a light area indicates the position of an exposure image when shift processing and control of reset timing has been controlled.

When the rear edge of the substrate 12 is photographed by the camera 26, exposure processing ends. Then, the movable stage 14 is moved to the upstream end of the movement path again.

According to the exposure apparatus using the first embodiment of the present invention, a relative positional deviation between the substrate 12 and the exposure head 30 during exposure for forming an exposure image is obtained as a real-time displacement amount of the movable stage 14. Then, the formation positions of exposure points by the exposure head 30 are corrected based on the obtained real-time displacement amount. Therefore, for example, even if the relative position of the substrate 12 and the exposure head 30 is temporarily shifted (deviated) because of vibration caused by the setting condition of the apparatus, the formation positions of the exposure points can be corrected in real time based on the positional deviation. Accordingly, it is possible to form an exposure image at a desirable position of the substrate 12. Consequently, it is possible to prevent the image quality from becoming lower because of the vibration.

Further, in the exposure apparatus using the first embodiment, correction processing is performed by taking the displacement amount of the movable stage 14 that has been measured in advance into consideration in addition to the real-time displacement amount of the movable stage 14. Therefore, it is possible to correct not only temporary positional deviation caused by vibration induced by the setting condition but positional deviation caused by pitching vibration or meandering of the movable stage 14. Hence, it is possible to position the exposure image even more accurately.

Further, the exposure position of the exposure image is corrected by controlling the reset timing based on the real-time displacement amount with respect to Y direction. Therefore, for example, if this correction method is compared with a method for correcting the position by performing shift processing on the exposure image data with respect to a direction corresponding to Y direction, this correction method is not limited by the resolution of the exposure image data. In this correction method, correction at high resolution is possible.

Further, a real-time displacement amount is obtained for each of the exposure heads 30 and correction is performed based on the real-time displacement amount for each of the exposure heads 30. Therefore, when this method is compared with a method for performing correction by obtaining the same real-time displacement amount for all of the exposure heads 30, very accurate positioning is possible in this method.

Next, an exposure apparatus using a second embodiment of a drawing method and a drawing apparatus of the present invention will be described.

An exposure apparatus 15 using the second embodiment of the present invention differs from the exposure apparatus 10 using the first embodiment of the present invention in its correction method based on a real-time displacement amount of the movable stage 14 with respect to X direction. In the exposure apparatus using the first embodiment of the present invention, shift processing is performed on divided exposure image data for each of the exposure heads 30 based on a real-time level amount of the movable stage 14 with respect to X direction. However, in the exposure apparatus 15 according to the present embodiment, shift processing is performed on the divided exposure image data only based on the meander line stored in the X-direction displacement amount storage memory 50. The exposure apparatus 15 performs correction processing for real-time displacement amounts X1 through XN of the respective exposure heads 30 obtained by the X-direction displacement amount calculation unit 81, as described below.

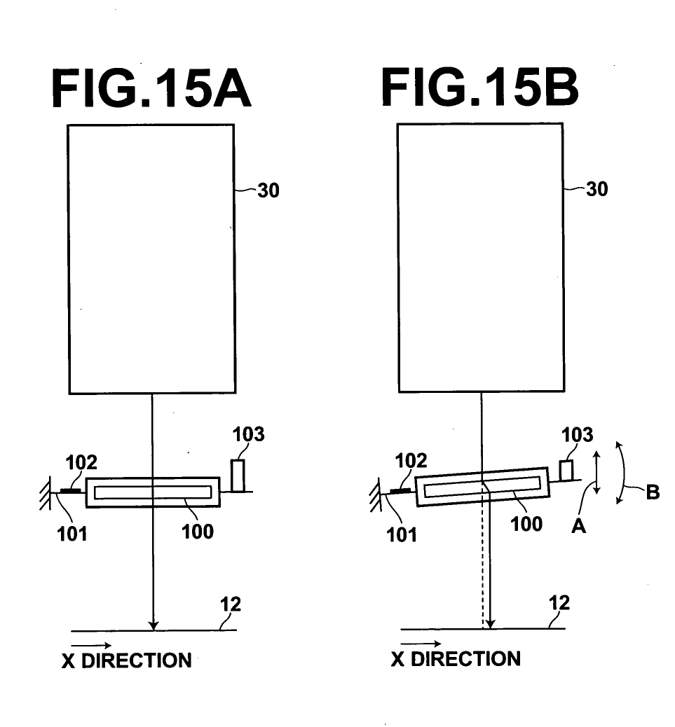

In the exposure apparatus 15, a parallel flat plate 100 made of glass or the like is set for each of the exposure heads 30, as illustrated in FIG. 15. The parallel flat plate 100 is positioned orthogonal to the optical axis of each of the exposure heads 30. Further, the parallel flat plate 100 is supported rotatably with respect to an axis (shaft) that is parallel to Y direction. Further, a leaf spring 101 is provided at one end of the parallel flat plate 100 with respect to X direction. Further, one end of the leaf spring 101 is fixed onto a part of a case of the exposure apparatus 15. Further, a distortion gauge 102 is provided in the leaf spring 101. Further, a piezo actuator 103 is provided at another end of the parallel flat plate 100. In the present embodiment, the parallel flat plate 100, the leaf spring 101, the distortion gauge 102 and the piezo actuator 103 form the optical system recited in the claims of the present application.

The piezo actuator 103 expands or contracts in the direction of arrow A illustrated in FIG. 15B based on the input control signal and the output result by the distortion gauge 102. Further, the parallel flat plate 100 moves rotationally in the direction of arrow B by expansion or contraction of the piezo actuator 103 in the direction of arrow A.

Further, the irradiation position of laser light on the substrate 12 with respect to X direction can be moved as illustrated in FIG. 3B by rotationally moving the parallel flat plate 100 in the direction of arrow B, as described above. The laser light is light output from the exposure head 30.

Therefore, in the exposure apparatus 15, control signals of the piezo actuators 103 are generated based on the real-time displacement amounts X1 through XN that have been obtained for the exposure heads 30, respectively. The control signals are generated for the respective exposure heads 30 based on the respective real-time displacement amounts X1 through XN. The generated control signals are sequentially input to the piezo actuators 103.

Then, each of the piezo actuators 103 expands or contracts based on the control signal, which has been generated as described above. Accordingly, it is possible to move the laser light that has been output from the exposure heads 3 with respect to X direction by amounts based on the real-time displacement amounts X1 through XN, respectively.

In the present embodiment, an effect similar to that obtained by the exposure apparatus 10 using the first embodiment of the present invention can be achieved by performing the aforementioned processing.

In the exposure apparatus 15 using the second embodiment, correction with respect to X direction is performed using an optical system. In contrast, in the exposure apparatus 10 using the first embodiment, correction is performed by performing shift processing on exposure image data. When these two methods are compared with each other, the method according to the second embodiment is not limited by the resolution of the exposure image data and correction at high resolution is possible.

In the aforementioned embodiments, the displacement amount of the movable stage 14 with respect to X direction and the displacement amount of the movable stage 14 with respect to Y direction are obtained in advance by photographing the markings 13 provided on the movable stage 14 in advance. However, it is not necessary that the markings 13 are provided. The displacement amount of the movable stage 14 with respect to X direction and the displacement amount of the movable stage 14 with respect to Y direction may be obtained in advance using a laser length meter. Then, the obtained displacement amount with respect to X direction may be stored in the X-direction displacement amount storage memory 50. Further, the pulse correction number may be stored in the pulse correction number storage memory 60.

Further, in the aforementioned embodiments, the displacement amount of the movable stage 14 with respect to X direction is stored in the X-direction displacement amount storage memory 50 in advance. Further, the pulse correction number is stored in the pulse correction number storage memory 60 in advance. Then, correction processing is performed based on these kinds of information that have been stored in advance and the real-time displacement amount of the movable stage 14 during exposure of the substrate 12 to light. However, it is not always necessary that the displacement amount of the movable stage 14 with respect to X direction and the correction pulse number are obtained in advance. The correction processing may be performed by using only the real-time displacement amount of the movable stage 14 during exposure of the substrate 12 to light.

Further, in the aforementioned embodiments, the real-time displacement amount of the movable stage 14 with respect to Y direction is corrected by controlling the reset timing of each of the exposure heads 30. Alternatively, shift processing with respect to Y direction may be performed on the divided exposure image data based on the real-time displacement amount with respect to Y direction.

Further, in the first and second embodiments, the real-time displacement amount is obtained based on the position information about the movable stage 14 and correction is performed based on the real-time displacement amount. Alternatively, position information about the exposure head 30 may be measured in addition to the position information about the movable stage 14. Then, a relative real-time displacement amount with respect to X direction and a relative real-time displacement amount with respect to Y direction may be obtained based on the position information about the movable stage 14 and the position information about the exposure head 30. Then, correction processing may be performed based on the relative real-time displacement amounts.

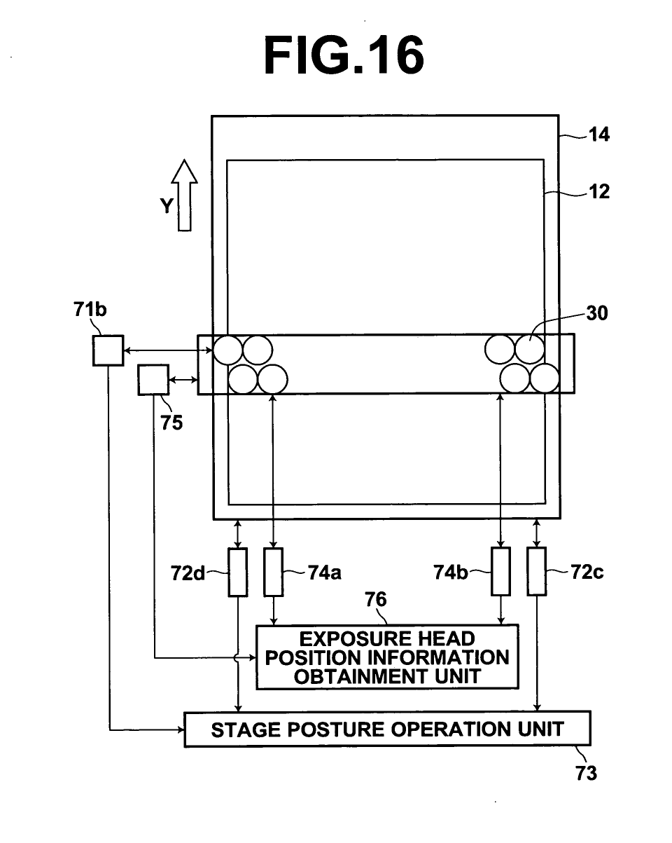

Specifically, as illustrated in FIG. 16, an X-direction laser length-measurement unit 75 for an exposure head and Y-direction laser length-measurement units 74a and 74b for an exposure head may be provided. The X-direction laser length-measurement unit 75 for an exposure head obtains position information about the exposure head 30 with respect to X direction. The Y-direction laser length-measurement units 74a and 74b for an exposure head obtain position information about the exposure head 30 with respect to Y direction. Then, the position information about the exposure head 30 with respect to X and Y directions may be obtained by the exposure head position information obtainment unit 76. In FIG. 16, a mirror corresponding to each of the laser length-measurement units is not illustrated.

Then, with respect to X direction, a relative real-time displacement amount X may be calculated based on the position information about the exposure head 30 that has been obtained by the exposure head position information obtainment unit 76 and the position information about the movable stage 14 that has been obtained by the stage posture operation unit 73. The relative real-time displacement amount X may be calculated using the following equation. Then, correction processing may be performed in a manner similar to the correction processing performed in the first or second embodiment.

X=(X1−XH)×A

X1: Position information about the movable stage 14 with respect to X direction, the information obtained by measurement by the X-direction laser length-measurement unit 71b

XH: Position information about the exposure head 30 with respect to X direction, the information obtained by measurement by the X-direction laser length-measurement unit 75 for the exposure head

A: An arbitrary constant

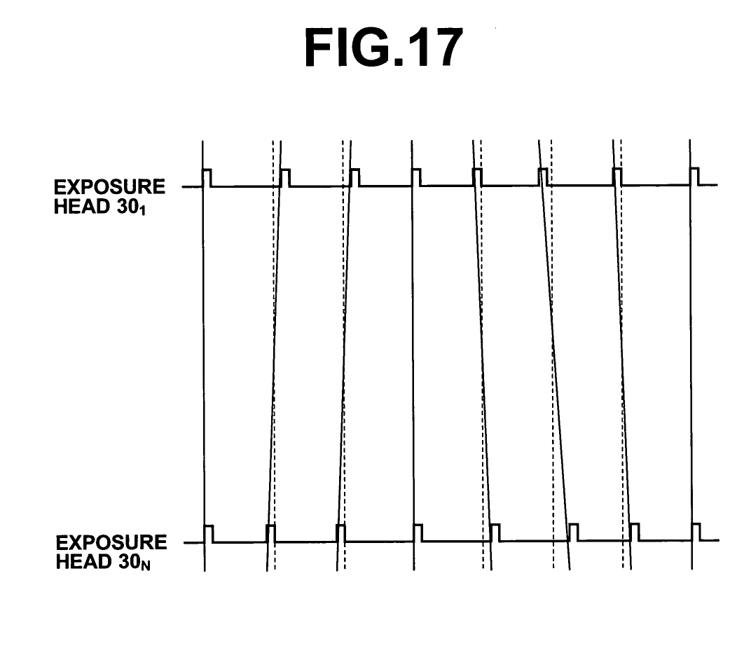

Further, with respect to Y direction, a relative real-time displacement amount Y may be calculated based on the position information about the exposure head 30 that has been obtained by the exposure head position information obtainment unit 76 and the position information about the movable stage 14 that has been obtained by the stage posture operation unit 73. The relative real-time displacement amount Y for each of the exposure heads 30 may be calculated using the following equation. Then, correction processing may be performed based on the relative real-time displacement amount Y by changing the exposure timing (by increasing or reducing time from the previous exposure) of each of the exposure heads 30_{N}, as illustrated in FIG. 17. The pulse waveform illustrated in FIG. 17 indicates exposure timing of each of the exposure heads 230_{N}. The broken lines in FIG. 17 indicate exposure timing of the exposure head 30_{N} when no relative positional deviation between the movable stage 14 and the exposure head is present. The solid lines in FIG. 17 indicate exposure timing of the exposure head 30_{N} when a positional deviation between the movable stage 14 and the exposure head is present.

Y=(Y1+Y2)/2+(Y1−Y2)×A(N)+(YH1−YH2)×B(N)

Y1: Position information about the movable stage 14 with respect to Y direction, the information obtained by measurement by the Y-direction laser length-measurement unit 72d

Y2: Position information about the movable stage 14 with respect to Y direction, the information obtained by measurement by the Y-direction laser length-measurement unit 72c

YH1: Position information about the exposure head 30 with respect to Y direction, the information obtained by measurement by the Y-direction laser length-measurement unit 74a for the exposure head

YH2: Position information about the exposure head 30 with respect to Y direction, the information obtained by measurement by the Y-direction laser length-measurement unit 74b for the exposure head

Further, A(N) and B (N) are constants provided for each of the exposure heads 30_{N}. The constants are determined based on the position of each of the exposure heads 30_{N}, which is an operation object, with respect to the central position of the exposure heads 30₁ through 30_{N}. The constants are smaller if the exposure head is positioned closer to the central position. The constants are larger if the exposure head is positioned far from the central position.

Further, in the aforementioned embodiment, shift processing is performed on the image data and the exposure timing is controlled based on the relative positional deviation between the movable stage 14 and the exposure head 30. However, it is not necessary that processing is performed in such a manner. For example, the movable stage 14 may be moved in X direction, Y direction and/or θ direction in such a manner that the relative positional deviation is suppressed (reduced).

Further, the position information about the movable stage 14 with respect to X direction, which has been obtained by the X-direction laser length-measurement unit 71b, and the position information about the movable stage 14 with respect to Y direction, which has been obtained by the Y-direction laser length-measurement units 72d and 72c, may be utilized to obtain the relative real-time displacement amount, as described above. These kinds of information may be utilized to control the position of the movable stage 14.

Further, in the aforementioned embodiments, an exposure apparatus including a DMD as a spatial light modulator has been described. However, a transmission-type spatial light modulator may be used instead of the reflection-type spatial light modulator, such as the DMD.

Further, in the aforementioned embodiment, a so-called flat-bed-type exposure apparatus was used as an example of the exposure apparatus. However, the exposure apparatus may be a so-called outer-drum-type exposure apparatus. The outer-drum-type exposure apparatus includes a drum about which a photosensitive material is wound.

Further, the substrate 12, which is an exposure object in the aforementioned embodiments, is not limited to a printed circuit board. The substrate 12 may be a substrate of a flat panel display. Further, the shape of the substrate 12 may be either sheet form or longitudinal form (a flexible substrate or the like).

Further, the drawing method and apparatus of the present invention may be applied to drawing in a printer, such as an ink-jet printer.

1-24. (canceled)

25. A drawing method for drawing an image on a substrate by relatively moving a drawing head that forms, based on input drawing-point data, drawing points on the substrate with respect to the substrate and by sequentially forming the drawing points on the substrate by the drawing head based on the movement of the drawing head, the method comprising:
obtaining a relative positional deviation between the substrate and the drawing head during drawing of the image; and
correcting, based on the obtained relative positional deviation, formation positions of the drawing points by the drawing head.

26. A drawing method, as defined in claim 25, wherein a relative positional deviation between the substrate and the drawing head with respect to the direction of the movement during drawing of the image is obtained and a relative positional deviation between the substrate and the drawing head with respect to a direction orthogonal to the direction of the movement during drawing of the image is obtained.

27. A drawing method, as defined in claim 26, wherein the position of a stage, on which the substrate is mounted, with respect to the direction of the movement and the position of the drawing head with respect to the direction of the movement during drawing of the image are obtained, and wherein the relative positional deviation with respect to the direction of the movement is obtained based on the position of the stage with respect to the direction of the movement and the position of the drawing head with respect to the direction of the movement.

28. A drawing method, as defined in claim 27, wherein a result of obtainment of the position of the stage, on which the substrate is mounted, with respect to the direction of the movement during drawing of the image is used to control the position of the stage and to obtain the relative positional deviation with respect to the direction of the movement.

29. A drawing method, as defined in claim 26, wherein the position of a stage, on which the substrate is mounted, with respect to the direction orthogonal to the direction of the movement during drawing of the image and the position of the drawing head with respect to the direction orthogonal to the direction of the movement during drawing of the image are obtained, and wherein the relative positional deviation with respect to the direction orthogonal to the direction of the movement is obtained based on the position of the stage with respect to the direction orthogonal to the direction of the movement and the position of the drawing head with respect to the direction orthogonal to the direction of the movement.

30. A drawing method, as defined in claim 29, wherein a result of obtainment of the position of the stage, on which the substrate is mounted, with respect to the direction orthogonal to the direction of the movement during drawing of the image is used to control the position of the stage and to obtain the relative positional deviation with respect to the direction orthogonal to the direction of the movement.

31. A drawing method, as defined in claim 25, wherein the formation positions of the drawing points are corrected by controlling, based on the relative positional deviation with respect to the direction of the movement, timing of formation of the drawing points by the drawing head.

32. A drawing method, as defined in claim 25, wherein a stage, on which the substrate is mounted, is controlled so that a relative positional deviation with respect to the direction of the movement is suppressed.

33. A drawing method, as defined in claim 25, wherein the formation positions of the drawing points are corrected by performing, based on the relative positional deviation with respect to a direction orthogonal to the direction of the movement, shift processing on image data representing the image, the image data including the drawing-point data, with respect to a direction corresponding to the direction orthogonal to the direction of the movement.

34. A drawing method, as defined in claim 25, wherein a stage, on which the substrate is mounted, is controlled so that a relative positional deviation with respect to a direction orthogonal to the direction of the movement is suppressed.

35. A drawing method, as defined in claim 25, wherein the drawing head forms the drawing points by illuminating the substrate with a light beam by outputting the light beam, and wherein an optical system that can move, with respect to a direction orthogonal to the direction of the movement, an illumination position of the light beam that has been output from the drawing head is provided, and wherein the formation positions of the drawing points are corrected by moving, based on a relative positional deviation with respect to the direction orthogonal to the direction of the movement, the illumination position of the light beam in the direction orthogonal to the direction of the movement using the optical system.

36. A drawing method, as defined in claim 25, wherein a plurality of drawing heads are provided, and wherein a relative positional deviation for each of the drawing heads is obtained based on a relative positional relationship between each of the drawing heads and the substrate.

37. A drawing apparatus, wherein an image is drawn on a substrate by relatively moving a drawing head that forms, based on input drawing-point data, drawing points on the substrate with respect to the substrate and by sequentially forming the drawing points on the substrate by the drawing head based on the movement of the drawing head, the apparatus comprising:
a positional deviation obtainment means for obtaining a relative positional deviation between the substrate and the drawing head during drawing of the image; and
a correction means for correcting, based on the relative positional deviation obtained by the positional deviation obtainment means, formation positions of the drawing points by the drawing head.

38. A drawing apparatus, as defined in claim 37, wherein the positional deviation obtainment means obtains a relative positional deviation between the substrate and the drawing head with respect to the direction of the movement during drawing of the image and a relative positional deviation between the substrate and the drawing head with respect to a direction orthogonal to the direction of the movement during drawing of the image.

39. A drawing apparatus, as defined in claim 38, wherein the positional deviation obtainment means obtains the position of a stage, on which the substrate is mounted, with respect to the direction of the movement and the position of the drawing head with respect to the direction of the movement during drawing of the image, and wherein the positional deviation obtainment means obtains the relative positional deviation with respect to the direction of the movement based on the position of the stage with respect to the direction of the movement and the position of the drawing head with respect to the direction of the movement.

40. A drawing apparatus, as defined in claim 39, wherein a result of obtainment of the position of the stage, on which the substrate is mounted, with respect to the direction of the movement during drawing of the image is used to control the position of the stage and to obtain the relative positional deviation with respect to the direction of the movement.

41. A drawing apparatus, as defined in claim 38, wherein the positional deviation obtainment means obtains the position of a stage, on which the substrate is mounted, with respect to the direction orthogonal to the direction of the movement during drawing of the image and the position of the drawing head with respect to the direction orthogonal to the direction of the movement during drawing of the image, and wherein the positional deviation obtainment means obtains the relative positional deviation with respect to the direction orthogonal to the direction of the movement based on the position of the stage with respect to the direction orthogonal to the direction of the movement and the position of the drawing head with respect to the direction orthogonal to the direction of the movement.

42. A drawing apparatus, as defined in claim 41, wherein a result of obtainment of the position of the stage, on which the substrate is mounted, with respect to the direction orthogonal to the direction of the movement during drawing of the image is used to control the position of the stage and to obtain the relative positional deviation with respect to the direction orthogonal to the direction of the movement.

43. A drawing apparatus, as defined in claim 37, wherein the correction means corrects the formation positions of the drawing points by controlling, based on the relative positional deviation with respect to the direction of the movement, timing of formation of the drawing points by the drawing head.

44. A drawing apparatus, as defined in claim 37, wherein the correction means controls a stage, on which the substrate is mounted, so that a relative positional deviation with respect to the direction of the movement is suppressed.

45. A drawing apparatus, as defined in claim 37, wherein the correction means corrects the formation positions of the drawing points by performing, based on the relative positional deviation with respect to a direction orthogonal to the direction of the movement, shift processing on image data representing the image, the image data including the drawing-point data, with respect to a direction corresponding to the direction orthogonal to the direction of the movement.

46. A drawing apparatus, as defined in claim 37, wherein the correction means controls a stage, on which the substrate is mounted, so that a relative positional deviation with respect to a direction orthogonal to the direction of the movement is suppressed.

47. A drawing apparatus, as defined in claim 37, wherein the drawing head forms the drawing points by illuminating the substrate with a light beam by outputting the light beam, and wherein an optical system that can move, with respect to a direction orthogonal to the direction of the movement, an illumination position of the light beam that has been output from the drawing head is provided, and wherein the correction means corrects the formation positions of the drawing points by moving, based on a relative positional deviation with respect to the direction orthogonal to the direction of the movement, the illumination position of the light beam in the direction orthogonal to the direction of the movement using the optical system.

48. A drawing apparatus, as defined in claim 37, wherein a plurality of drawing heads are provided, and wherein the positional deviation obtainment means obtains a relative positional deviation for each of the drawing heads based on a relative positional relationship between each of the drawing heads and the substrate.
